(19) United States
(12) Patent Application Publication
(10) Pub. No.: US 2026/0344328 A1
(43) Pub. Date: Oct. 29, 2026

(54) SCRUBBING APPARATUS

(71) Applicant: Seung Hwan OH, Seoul (KR)

(72) Inventors: Seung Hwan OH, Seoul (KR); Gunho SHIN, Seoul (KR)

(21) Appl. No.: 19/566,272

(22) Filed: Mar. 13, 2026

Related U.S. Application Data
(63) Continuation of application No. PCT/KR2025/006138, filed on May 8, 2025.

(30) Foreign Application Priority Data
Apr. 28, 2025 (KR) 10-2025-0055453

(51) Int. Cl. H10P 72/00

(52) U.S. Cl. CPC H10P 72/0412; H10P 72/0604; H10P 72/0414

(57) ABSTRACT

The scrubbing apparatus of present disclosure comprises a first inlet chamber connected to a process chamber, a first scrubbing chamber connected to the first inlet chamber and defining a first scrubbing space for primarily scrubbing gas generated from the process chamber, a second inlet chamber connected to the first scrubbing chamber, a second scrubbing chamber connected to the second inlet chamber and defining a second scrubbing space for secondarily scrubbing the gas, a first pressure controller disposed in the first inlet chamber and configured to maintain a constant pressure of the gas provided from the process chamber to the first inlet chamber, and a second pressure controller disposed in the second inlet chamber and configured to maintain a constant pressure of the gas discharged from the second scrubbing chamber.

### TECHNICAL FIELD

The present disclosure relates to a scrubbing apparatus. More particularly, the present disclosure relates to a scrubbing apparatus that improves scrubbing efficiency and space efficiency by using a plurality of scrubbers, and that enhances stability of a process chamber and a utility duct by controlling a pressure of gas provided from the process chamber and a pressure of the gas discharged after a scrubbing process is performed.

### BACKGROUND ART

In modern industries, various types of air pollutants are generated, many of which have extremely low permissible exposure limits for humans. Accordingly, removing air pollutants from gases emitted in various industrial fields before discharge is a critical issue.

Currently used air pollution prevention facilities include dust collectors and scrubbers, and they are installed considering their efficiency depending on the type of pollutant. Among these, scrubbers are widely used because they can simultaneously process dust, exhaust gas, and high-temperature gas.

Specifically, scrubbers are classified into dry, wet, and plasma types depending on the method of treating the exhaust gas, and wet scrubbers are used in a process that causes the exhaust gas to come into contact with a liquid to dissolve water-soluble components in the gas into the liquid.

In wet scrubbers, a cleaning solution is generally used to effectively remove harmful components of the exhaust gas. When the cleaning solution comes into contact with harmful components, it removes the harmful components through a chemical reaction such as neutralization, so the one that best reacts chemically with the harmful components of the emitted gas should be selected. The performance of the wet scrubber is determined by whether the solution containing the cleaning solution can efficiently contact the exhaust gas. Accordingly, in the related art, a filler is installed to ensure sufficient contact between the cleaning solution and the discharged gas, and a spray nozzle is employed to supply a cleaning solution having fine particles.

Recently, a technology that can improve the contact area between the scrubbing solution containing the cleaning solution and the exhaust gas has been studied.

### SUMMARY

### TECHNICAL PROBLEM

The technical problem to be solved by the present disclosure is to provide a scrubbing apparatus that improves scrubbing efficiency by enhancing a contact area between a scrubbing solution and gas, that improves space efficiency by using a plurality of scrubbers, and that enhances stability of a process chamber and a utility duct by controlling a pressure of the gas.

The problems that the present disclosure is trying to solve are not limited to the problems mentioned above, and other problems that are not mentioned can be clearly understood by those skilled in the art from the description below.

### SOLUTION TO PROBLEM

A scrubbing apparatus according to some embodiments of the present disclosure for achieving the above technical problem comprises a first inlet chamber connected to a process chamber, a first scrubbing chamber connected to the first inlet chamber and defining a first scrubbing space for primarily scrubbing gas generated from the process chamber, a second inlet chamber connected to the first scrubbing chamber, a second scrubbing chamber connected to the second inlet chamber and defining a second scrubbing space for secondarily scrubbing the gas, a first pressure controller disposed in the first inlet chamber and configured to maintain a constant pressure of the gas provided from the process chamber to the first inlet chamber, and a second pressure controller disposed in the second inlet chamber and configured to maintain a constant pressure of the gas discharged from the second scrubbing chamber.

By maintaining the pressure of the gas supplied from the process chamber to the first inlet chamber at a constant level, a load applied to the process chamber may be reduced. In addition, by maintaining the pressure of the gas discharged from the second scrubbing chamber at a constant level, a load applied to the utility duct may be reduced.

In some embodiments, wherein the first inlet chamber, the first scrubbing chamber, and the second inlet chamber are overlapped in a first direction, and wherein the second inlet and the second scrubbing chamber are overlapped in a second direction intersecting the first direction.

In some embodiments, wherein the first inlet chamber and the first scrubbing chamber are connected to each other at a lower part, wherein a bottom surface of the first inlet chamber includes a first portion inclined downward, and wherein the first portion extends between the first direction and a third direction intersecting the first and second directions.

In some embodiments, wherein the second inlet chamber and the second scrubbing chamber are connected to each other at a lower part, wherein a bottom surface of the second inlet chamber includes a second portion inclined downward, and wherein the second portion extends between the second direction and the third direction.

In some embodiments, wherein the first inlet chamber is overlapped with the first scrubbing chamber in a third direction, and wherein the second inlet chamber is overlapped with the second scrubbing chamber in the third direction.

In some embodiments, wherein the first scrubbing chamber includes a first_1 scrubbing space and a first_2 scrubbing space, and wherein the first_1 scrubbing space and the first_2 scrubbing space are connected to each other at a lower part.

A scrubbing apparatus according to some embodiments of the present disclosure further comprises a first scrubbing plate disposed in the first scrubbing chamber, at least a portion of which is fixed to an inner side wall of the first scrubbing chamber, a plurality of first scrubbing holes penetrating the first scrubbing plate, a first solution supply nozzle configured to supply a first scrubbing solution onto an upper surface of the first scrubbing plate, a second scrubbing plate disposed in the second scrubbing chamber, at least a portion of which is fixed to an inner side wall of the second scrubbing chamber, a plurality of second scrubbing holes penetrating the second scrubbing plate and a second solution supply nozzle configured to supply a second scrubbing solution onto an upper surface of the second scrubbing plate, wherein a portion of impurities contained in the gas ascend through the plurality of first scrubbing holes in the first scrubbing chamber and are dissolved in the first scrubbing solution, and wherein another portion of the impurities contained in the gas ascend through the plurality of second scrubbing holes in the second scrubbing chamber and are dissolved in the second scrubbing solution.

A scrubbing apparatus according to some embodiments of the present disclosure further comprises a first pressure sensor configured to measure a first pressure of the gas provided to the first inlet chamber, wherein the first pressure controller includes a first rotation module rotatable, wherein when an absolute value of the first pressure measured by the first pressure sensor is greater than a first pressure set value, a rotation speed of the first rotation module is decreased, and wherein when the absolute value of the first pressure measured by the first pressure sensor is less than the first pressure set value, the rotation speed of the first rotation module is increased.

In some embodiments, wherein the second pressure controller includes a second rotation module rotatable, wherein when an absolute value of the first pressure is greater than a first pressure set value, a rotation speed of the second rotation module is decreased, and wherein when the absolute value of the first pressure is less than the first pressure set value, the rotation speed of the second rotation module is increased.

A scrubbing apparatus according to some embodiments of the present disclosure further comprises a second pressure sensor configured to measure a second pressure of the gas discharged through the second scrubbing chamber, wherein the second pressure controller includes a second rotation module rotatable, wherein when an absolute value of the second pressure measured by the second pressure sensor is greater than a second pressure set value, a rotation speed of the second rotation module is decreased, and wherein when the absolute value of the second pressure measured by the second pressure sensor is less than the second pressure set value, the rotation speed of the second rotation module is increased.

In some embodiments, wherein the second pressure is 0 Pa.

A scrubbing apparatus according to other embodiments of the present disclosure for achieving the above technical problem comprises a first scrubber configured to primarily scrub gas, a first inlet chamber disposed at one end of the first chamber, a first rotation module disposed in the first inlet chamber, a second scrubber configured to secondarily scrub the gas, a second inlet chamber disposed between the second scrubber and the first scrubber and a second rotation module disposed in the second inlet chamber, wherein the first scrubber includes a first scrubbing chamber defining a first scrubbing space for scrubbing impurities contained in the gas, a first scrubbing plate disposed in the first scrubbing chamber, at least a portion of which is fixed to an inner side wall of the first scrubbing chamber, a plurality of first scrubbing holes penetrating the first scrubbing plate and a first solution supply nozzle configured to supply a first scrubbing solution onto an upper surface of the first scrubbing plate, wherein the second scrubber includes a second scrubbing chamber defining a second scrubbing space for scrubbing the impurities contained in the gas, a second scrubbing plate disposed in the second scrubbing chamber, at least a portion of which is fixed to an inner side wall of the second scrubbing chamber, a plurality of second scrubbing holes penetrating the second scrubbing plate, and a second solution supply nozzle configured to supply a second scrubbing solution onto an upper surface of the second scrubbing plate, wherein when a pressure of the gas provided to the first scrubbing chamber is higher than a predetermined value, a rotation speed of the first rotation module is decreased, and wherein when a pressure of the gas discharged from the second scrubbing chamber is higher than a predetermined value, a rotation speed of the second rotation module is decreased.

In some embodiments, wherein a portion of the impurities contained in the gas ascend through the plurality of first scrubbing holes in the first scrubbing chamber and are dissolved in the first scrubbing solution, and wherein another portion of the impurities contained in the gas ascend through the plurality of second scrubbing holes in the second scrubbing chamber and are dissolved in the second scrubbing solution.

A scrubbing apparatus according to some embodiments of the present disclosure further comprises a third pressure sensor configured to measure a third pressure of the gas in the first scrubbing chamber, wherein the third pressure includes a first section, a second section, and a third section, wherein when the third pressure is in the first section, a flow rate of the first scrubbing solution is increased, and wherein when the third pressure is in the third section, the gas is not introduced into the first scrubbing chamber.

In some embodiments, wherein the first scrubber further comprises a first scrubbing solution storage tank in which a first scrubbing solution, in which impurities are dissolved, is stored, wherein the first inlet chamber is overlapped with the first scrubbing chamber in a first direction, and wherein the first scrubbing solution storage tank is overlapped with the first inlet chamber and the first scrubbing chamber in a third direction intersecting the first direction.

In some embodiments, wherein the first scrubber further comprises a first scrubbing wall attached to one end of the first scrubbing plate, and wherein at least a portion of the first scrubbing wall is disposed in the first scrubbing solution in which impurities are dissolved.

A scrubbing apparatus according to some embodiments of the present disclosure further comprises a first pipe through which the gas is injected into the scrubbing apparatus and a second pipe through which the gas is discharged to an outside of the scrubbing apparatus wherein the first pipe is not overlapped with the first scrubber in a third direction, and wherein the second pipe is overlapped with the second scrubber in the third direction.

Specific details of other embodiments are included in the specification and drawings.

### EFFECT OF INVENTION

The scrubbing apparatus of the present disclosure includes at least one scrubbing plate. Scrubbing holes penetrating the scrubbing plate is formed inside the scrubbing plate. While the gas ascends through the scrubbing holes, bubbles may be formed in a scrubbing solution flowing on an upper surface of the scrubbing plate.

As the bubbles are formed, a contact area between the scrubbing solution and the gas is increased. Since the contact area is increased, hydrophilic impurities contained in the gas can be more effectively dissolved in the scrubbing solution. Accordingly, gas from which contaminants (impurities) are removed can be discharged to the outside of the scrubbing apparatus.

In addition, a pressure of the gas provided from a process chamber to the scrubbing apparatus, and a pressure of the gas discharged from the scrubbing apparatus are constantly controlled, so that a load applied to the process chamber and a utility duct can be reduced.

Furthermore, by arranging an inlet chamber and a scrubbing chamber in a horizontal direction and lowering a height of the scrubbing apparatus, space utilization can be maximized.

### BRIEF DESCRIPTION OF DRAWINGS

FIG. 1 is a drawing briefly explaining a scrubbing system including a scrubbing apparatus to some embodiments of the present disclosure.

FIG. 2 is an exemplary plan view for explaining the scrubbing apparatus of FIG. 1.

FIG. 3 is a cross-sectional view taken along line A-A' of FIG. 2.

FIG. 4 is a cross-sectional view taken along line B-B' of FIG. 2.

FIG. 5 is an enlarged view of the P area of FIG. 3.

FIG. 6 is an enlarged view of the Q area of FIG. 2.

FIG. 7 is a drawing for explaining the scrubbing apparatus according to some other embodiments of the present disclosure.

FIG. 8 is a drawing for explaining the scrubbing apparatus according to some other embodiments of the present disclosure.

FIG. 9 is a cross-sectional view taken along line C-C' of FIG. 9.

FIGS. 10-13 are drawings for explaining the scrubbing apparatus according to some other embodiments of the present disclosure.

FIG. 14 is a drawing for explaining an operating method of a scrubbing apparatus according to some embodiments of the present disclosure.

### DETAILED DESCRIPTIONS OF EXEMPLARY EMBODIMENTS

Hereinafter, preferred embodiments of the present disclosure will be described in detail with reference to the accompanying drawings. The advantages and features of the present disclosure and the methods for achieving them will become apparent with reference to the embodiments described in detail below together with the accompanying drawings. However, the present disclosure is not limited to the embodiments described below, but may be implemented in various different forms, and these embodiments are provided only to make the disclosure of the present disclosure complete and to fully inform those skilled in the art of the scope of the disclosure, and the present disclosure is defined only by the scope of the claims. Like reference numerals refer to like elements throughout the specification.

In addition, the terminology used herein is for the purpose of describing embodiments, and is not intended to limit and/or restrict the disclosed disclosure. The singular expression includes the plural expression unless the context clearly indicates otherwise. In this specification, the terms "comprises", "include", or "has" and the like are intended to specify that a feature, number, step, operation, component, part, or combination thereof described in the specification is present, but do not exclude in advance the possibility of the presence or addition of one or more other features, numbers, steps, operations, components, parts, or combinations thereof.

In addition, terms including ordinal numbers such as "first", "second", etc. used in this specification may be used to describe various components, but the components are not limited by the terms, and the terms are used only for the purpose of distinguishing one component from another. For example, without departing from the scope of the present disclosure, the first component may be named the second component, and similarly, the second component may also be named the first component. The term "and/or" includes a combination of multiple related described items or any item among multiple related described items.

Meanwhile, the terms "front", "rear", "upper", "lower", "front", and "lower" used in the following description are defined based on the drawings, and the shape and position of each component are not limited by these terms.

The terms used in this specification are for describing embodiments and are not intended to limit the present disclosure. In this specification, the singular includes the plural unless specifically stated in the phrase. The terms "comprise" and/or "comprising" used in the specification do not exclude the presence or addition of one or more other components, steps, operations, and/or elements mentioned.

Unless otherwise defined, all terms (including technical and scientific terms) used in this specification may be used in a meaning that can be commonly understood by a person of ordinary skill in the art to which the present disclosure belongs. In addition, terms defined in commonly used dictionaries shall not be ideally or excessively interpreted unless explicitly specifically defined.

Hereinafter, embodiments of the present disclosure will be described in detail with reference to the attached drawings, and when describing with reference to the attached drawings, identical or corresponding components will be given the same reference numerals regardless of the drawing numbers, and redundant descriptions thereof will be omitted.

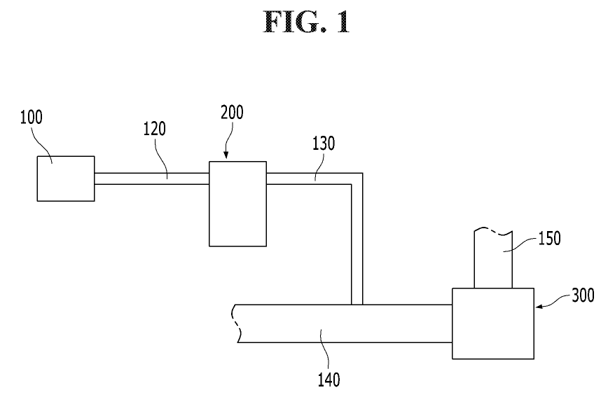

Hereinafter, first, a scrubbing system 1000 including a scrubbing apparatus 20 according to some embodiments of the present disclosure will be described with reference to FIG. 1. FIG. 1 is a drawing briefly explaining the scrubbing system including the scrubbing apparatus according to some embodiments of the present disclosure.

Referring to FIG. 1, the scrubbing system 1000 according to some embodiments of the present disclosure may include a process chamber 100, a scrubbing apparatus 200, a first pipe 120, a second pipe 130, a third pipe 140, a utility pipe 150, and a utility duct 300.

The process chamber 100 may be a chamber utilized in various industrial fields. The various industrial fields may be a plant field, a battery field, a thermal power plant field, a steel field, a semiconductor field, a chemical field, and/or an oil and gas plant field.

For example, the process chamber 100 may be a chamber in which a semiconductor process is performed. In order to manufacture a semiconductor device, various semiconductor processes must be performed on a wafer. For example, a film must be deposited on the wafer(deposition process), and the film must be etched (etching process) to form a pattern included in the semiconductor device. In addition, after the deposition process and/or the etching process are performed, a cleaning process must be performed to clean the wafer and/or the process chamber 10.

The deposition process may include, for example, physical vapor deposition (PVD), chemical vapor deposition (CVD), and/or atomic layer deposition (ALD). The etching process may include, for example, a dry etching process, a wet etching process, and/or an ashing process. The cleaning process may include, for example, a wet cleaning process, a dry cleaning process, and/or a vapor cleaning process.

According to another embodiment, the deposition process, the etching process, and/or the cleaning process may be performed simultaneously.

As another example, the process chamber 100 may be utilized in an oil and gas plant industry, and in this case, the process chamber 100 may be a chamber in which a plant process is performed.

When various semiconductor processes are performed in the process chamber 100, by-products may be generated. The by-products should be discharged to an outside of a semiconductor production line through a plurality of pipes. At this time, pressures and energy applied to the plurality of pipes should be controlled to effectively control the process chamber 100 and a utility duct 300. If the by-products contain substances harmful to the human body, the substances must necessarily be removed before being discharged.

A first pipe 120 may be disposed between the process chamber 100 and the scrubbing apparatus 200. The gas used in the semiconductor process performed in the process chamber 100 may be discharged to an outside of the process chamber 100 through the first pipe 120.

The first pipe 120 may be connected to the scrubbing apparatus 200. The first pipe 120 may connect the process chamber 100 and the scrubbing apparatus 200 to each other. The gas discharged from the process chamber 100 may be provided to the scrubbing apparatus 200 through the first pipe 120.

The scrubbing apparatus 200 may be disposed between the first pipe 120 and the second pipe 130. The gas is provided to the scrubbing apparatus 200 through the first pipe 120. The gas having passed through the scrubbing apparatus 200 may be discharged to an outside of the scrubbing apparatus 200 through the second pipe 130.

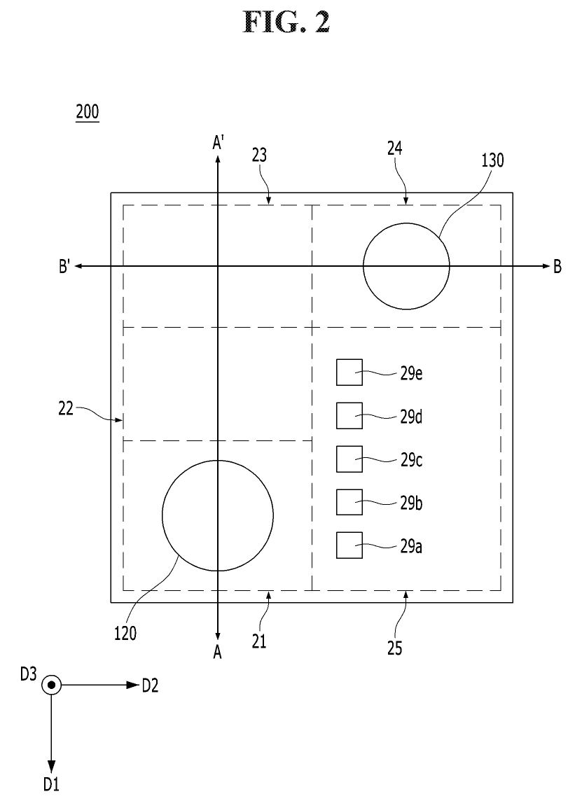

In some embodiments, the gas may have a pressure. For example, a pressure of the gas when passing through the first pipe 120 and a pressure of the gas when passing through the second pipe 130 may be different from each other. By using the scrubbing apparatus 200 according to some embodiments of the present disclosure, the pressure of the gas when passing through the first pipe 120 and the pressure of the gas when passing through the second pipe 130 can be individually controlled to be constant. Accordingly, a load applied to the process chamber 100 and a utility duct 300 is reduced, thereby increasing process efficiency of a semiconductor production line. Details related thereto will be described below with reference to FIGS. 2-14.

The second pipe 130 may be connected to the scrubbing apparatus 200. The gas having passed through the scrubbing apparatus 200 may be discharged to an outside of the scrubbing apparatus 200 through the second pipe 130. The second pipe 130 may be interposed between the scrubbing apparatus 200 and a third pipe 140.

The third pipe 140 may be interposed between the second pipe 130 and the utility duct 300. The third pipe 140 may be connected to the second pipe 130. The gas having passed through the second pipe 130 may be provided to the third pipe 140. The third pipe 140 may be provided to a floor space of a semiconductor production line.

The utility duct 300 may be connected to the third pipe 140. The utility duct 300 may provide a pressure to the third pipe 140. The gas may be moved by using the pressure provided by the utility duct 300. The gas having passed through the utility duct 300 may be discharged to an outside of the semiconductor production line through the utility pipe 150.

In some embodiments, the scrubbing apparatus 200 may include at least one scrubber. When a semiconductor process is performed in the process chamber 100, various by-products may be generated. The by-products may include substances harmful to the human body, and if the by-products include substances harmful to the human body, the substances must necessarily be removed before being discharged.

The at least one scrubber may be used to remove the substances harmful to the human body from the by-products generated in the process chamber 100. That is, the scrubbing apparatus 200 may scrub impurities contained in the gas while simultaneously reducing a pressure of the gas. The impurities may include hydrophilic substances. However, the technical scope of the present disclosure is not limited thereto.

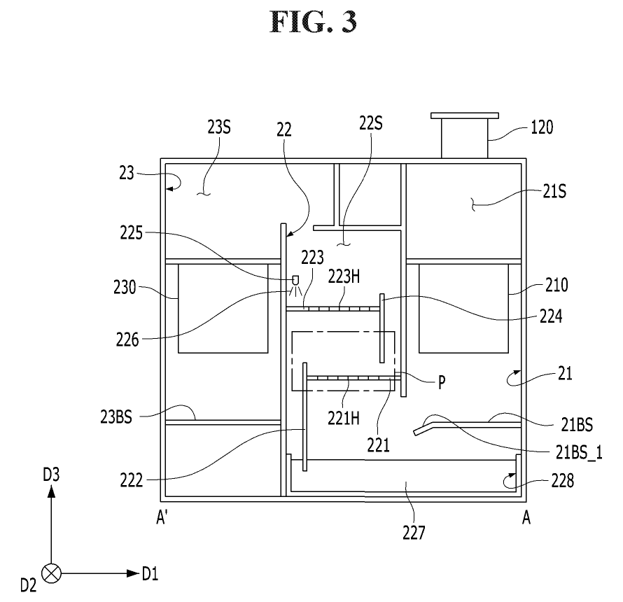

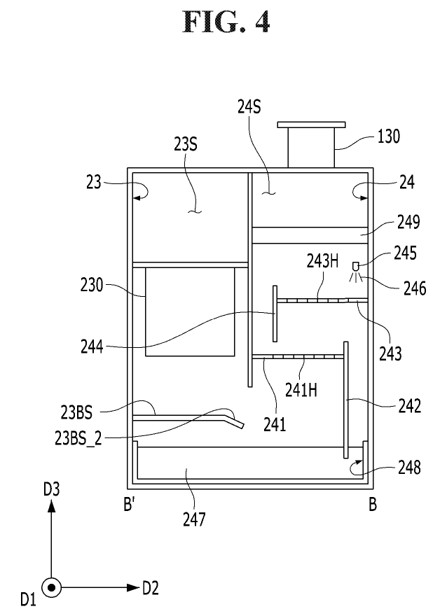

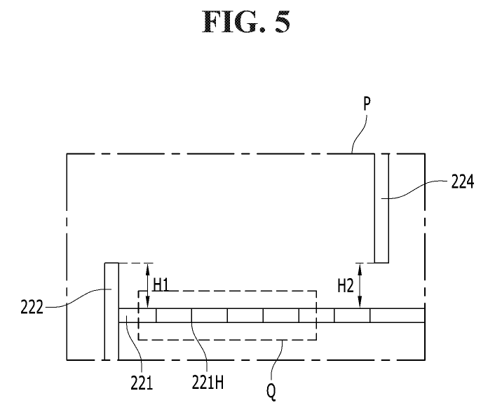

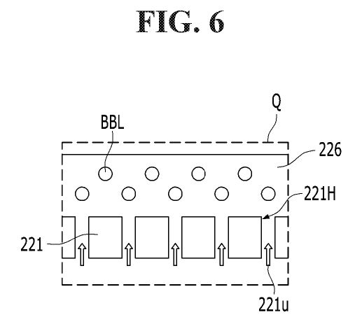

Hereinafter, referring to FIGS. 2-6, a scrubbing apparatus according to some embodiments of the present disclosure will be described. FIG. 2 is an exemplary plan view for explaining the scrubbing apparatus of FIG. 1. FIG. 3 is a cross-sectional view taken along line A-A' of FIG. 2. FIG. 4 is a cross-sectional view taken along line B-B' of FIG. 2. FIG. 5 is an enlarged view of the P area of FIG. 2. FIG. 6 is an enlarged view of the Q area of FIG. 2.

Referring to FIGS. 2-6, the scrubbing apparatus 200 according to some embodiments of the present disclosure may include a first inlet chamber 21, a first scrubbing chamber 22, a second inlet chamber 23, a second scrubbing chamber 24, and a sub-chamber 25. The first scrubbing chamber 22 may be an outer housing of a first scrubber that primarily scrubs the gas, and the second scrubbing chamber 24 may be an outer housing of a second scrubber that secondarily scrubs the gas. In the sub-chamber 25, a plurality of scrubbing solution pipes serving as passages for movement of a scrubbing solution, pressure sensors 29a, 29b, 29c, 29d, and 29e to be described below, and a controller configured to control pressure controllers 210 and 230 to be described below may be disposed.

In some embodiments, the first inlet chamber 21, the first scrubbing chamber 22, and the second inlet chamber 23 may be adjacent to each other in a first direction D1. The first inlet chamber 21, the first scrubbing chamber 22, and the second inlet chamber 23 may be overlapped with each other in the first direction D1. The first scrubbing chamber 22 may be interposed between the first inlet chamber 21 and the second inlet chamber 23.

The second inlet chamber 23 and the second scrubbing chamber 24 may be adjacent to each other in a second direction D2. The first direction D1 and the second direction D2 may intersect each other. In the present specification, a third direction D3 may intersect each of the first direction D1 and the second direction D2. The third direction D3 may be, for example, a vertical direction perpendicular to the ground, but the technical scope of the present disclosure is not limited thereto.

In some embodiments, by arranging the first inlet chamber 21, the first scrubbing chamber 22, the second inlet chamber 23, and the second scrubbing chamber 24 in a horizontal direction (the first direction D1 and the second direction D2) and lowering a height of the scrubbing apparatus 200, space utilization of a semiconductor production line may be maximized.

A first pressure controller 210 may be disposed in the first inlet chamber 21. The first inlet chamber 21 may define a first inlet space 21S. The first inlet space 21S may be a space in which the first pressure controller 210 is disposed and through which the gas moves.

In some embodiments, the first pressure controller 210 may include a first rotation module. The first rotation module may be rotatable. The first rotation module may rotate in a clockwise direction or a counterclockwise direction. By adjusting a rotation speed of the first rotation module, a pressure of the gas provided to the scrubbing apparatus 200 through the first pipe 120 may be controlled to a constant value.

In some embodiments, a bottom surface 21BS of the first inlet chamber 21 may include a first portion 21BS_1. The first portion 21BS_1 may be inclined downward. The first portion 21BS_1 may extend between the first direction D1 and the third direction D3. A flow path of the gas may be restricted by the first portion 21BS_1. The gas may enter the inside of the first scrubbing chamber 22 along the first portion 21BS_1. Since the first portion 21BS_1 has a shape inclined downward, the gas may also enter downward.

In FIG. 3, the first portion 21BS_1 is illustrated as not being disposed in a first scrubbing solution 227 in which impurities are dissolved, but the technical scope of the present disclosure is not limited thereto. It is to be understood that at least a portion of the first portion 21BS_1 may be disposed in the first scrubbing solution 227 in which the impurities are dissolved.

In some embodiments, a bottom surface 21BS of the first inlet chamber 21 may restrict a flow path of gas. For example, when the gas directly contacts water while descending in the third direction D3, the water may splash and flow into the first pressure controller 210. By forming the bottom surface 21BS of the first inlet chamber 21 to restrict the flow path of the gas, this may be prevented.

The first scrubber may be interposed between the first inlet chamber 21 and the second inlet chamber 23. The first scrubber may include a first scrubbing chamber 22, a first_1 scrubbing plate 221, a first_2 scrubbing plate 223, a first_1 scrubbing wall 222, a first_2 scrubbing wall 224, and a first solution supply nozzle 225.

The first scrubbing chamber 22 may be an outer housing of the first scrubber. The gas may be provided into the first scrubbing chamber 22. The gas may contain impurities. The gas may pass through the first inlet chamber 21 and be provided to the first scrubbing chamber 22. The gas may pass through the first inlet space 21S and the first pressure controller 210 and be provided to a lower part of the first scrubbing chamber 22.

For example, the gas may first be provided into the first inlet chamber 21 through the first pipe 120. The first pipe 120 may be formed on an upper wall of the first inlet chamber 21, or may be formed on a side wall of the first inlet chamber 21. In addition, the first pipe 120 may be formed on an upper portion of the side wall of the first inlet chamber 21, or may be formed on a lower portion of the side wall. The first inlet chamber 21 may be connected to the first scrubbing chamber 22 at a lower part of the first inlet chamber 21, and the gas may be provided into the first scrubbing chamber 22 through the connected space.

In the first scrubbing chamber 22, impurities contained in the gas may be dissolved in a first scrubbing solution 226. The first scrubbing chamber 22 may define a first scrubbing space 22S. The first scrubbing space 22S may be a space in which a first scrubbing process, in which impurities contained in the gas are dissolved in the first scrubbing solution 226, is performed.

A plurality of first scrubbing plates may be disposed in the first scrubbing space 22S. The plurality of first scrubbing plates may include, for example, a first_1 scrubbing plate 221 and a first_2 scrubbing plate 223.

In FIG. 3, the first scrubber is illustrated as including two first scrubbing plates, but the technical scope of the present disclosure is not limited thereto. The first scrubber according to some embodiments of the present disclosure may include one or more first scrubbing plates. That is, one first scrubbing plate may be disposed in the first scrubbing space 22S, or three or more first scrubbing plates may be disposed therein.

The first_1 scrubbing plate 221 may be disposed at a lowermost position among the first scrubbing plates disposed in the first scrubbing space 22S. One end of the first_1 scrubbing plate 221 may be connected to and fixed to an inner side wall of the first scrubbing chamber 22, and the other end of the first_1 scrubbing plate 221 may be spaced apart from the inner side wall of the first scrubbing chamber 22. Specifically, three surfaces of the first_1 scrubbing plate 221 may be connected to the inner side wall of the first scrubbing chamber 22, and a remaining one surface of the first_1 scrubbing plate 221 may not be connected to the inner side wall of the first scrubbing chamber 22. The first_1 scrubbing plate 221 may be disposed on a plane extending in the first direction D1 and the second direction D2. A space from the other end of the first_1 scrubbing plate 221 to the inner side wall of the first scrubbing chamber 22 may be a space through which the first scrubbing solution 226 to be described later flows downward (for example, in the third direction D3).

The first scrubber according to some embodiments may further include first_1 scrubbing holes 221H and a first_1 scrubbing wall 222.

The first_1 scrubbing holes 221H may be formed in the first_1 scrubbing plate 221. The first_1 scrubbing holes 221H may extend from a lower surface of the first_1 scrubbing plate 221 to an upper surface of the first_1 scrubbing plate 221. That is, the first_1 scrubbing holes 221H may penetrate the first_1 scrubbing plate 221 in the third direction D3. Gas may ascend in the third direction D3 through the first_1 scrubbing holes 221H (see reference numeral 221u).

The lower surface of the first_1 scrubbing plate 221 may face a first scrubbing solution storage tank 228 to be described later. The upper surface of the first_1 scrubbing plate 221 may face the first_2 scrubbing plate 223. The upper surface of the first_1 scrubbing plate 221 may be opposite to the lower surface of the first_1 scrubbing plate 221 in the third direction D3.

The first_1 scrubbing wall 222 may be attached to the other end of the first_1 scrubbing plate 221. The first_1 scrubbing wall 222 may be interposed between the first_1 scrubbing plate 221 and the inner side wall of the first scrubbing chamber 22. The first_1 scrubbing wall 222 may extend in the third direction D3. In some embodiments, a portion of the first_1 scrubbing wall 222 may protrude in the third direction D3 from the upper surface of the first_1 scrubbing plate 221. Another portion of the first_1 scrubbing wall 222 may protrude in the third direction D3 from the lower surface of the first_1 scrubbing plate 221.

A length of a portion of the first_1 scrubbing wall 222 protruding in the third direction D3 from the upper surface of the first_1 scrubbing plate 221 may be smaller than a length, in the third direction D3, of a portion protruding in the third direction D3 from the lower surface of the first_1 scrubbing plate 221, but the technical scope of the present disclosure is not limited thereto.

In some embodiments, at least a portion of the first_1 scrubbing wall 222 may be disposed in the first scrubbing solution 227 in which impurities are dissolved, but the technical scope of the present disclosure is not limited thereto. Since at least a portion of the first_1 scrubbing wall 222 is disposed in the first scrubbing solution 227 in which the impurities are dissolved, the gas may initially ascend in the third direction D3 through the first_1 scrubbing holes 221H. Since at least a portion of the first_1 scrubbing wall 222 is disposed in the first scrubbing solution 227 in which the impurities are dissolved, the gas may not ascend into a space between the first_1 scrubbing wall 222 and the inner side wall of the first scrubbing chamber 22.

The first_2 scrubbing plate 223 may be disposed on the first_1 scrubbing plate 221. Specifically, the first_2 scrubbing plate 223 may be disposed on the upper surface of the first_1 scrubbing plate 221.

Similar to the first_1 scrubbing plate 221, one end of the first_2 scrubbing plate 223 may be connected to and fixed to the inner side wall of the first scrubbing chamber 22, and the other end of the first_2 scrubbing plate 223 may be spaced apart from the inner side wall of the first scrubbing chamber 22. Specifically, three surfaces of the first_2 scrubbing plate 223 may be connected to and fixed to the inner side wall of the first scrubbing chamber 22. However, a remaining one surface of the first_2 scrubbing plate 223 may not be connected to and fixed to the inner side wall of the first scrubbing chamber 22. The one surface of the first_2 scrubbing plate 223 may be spaced apart from the first scrubbing chamber 22 in the first direction D1. A space from the one surface of the first_2 scrubbing plate 223 to the first scrubbing chamber 22 may be a space through which a first scrubbing solution 226 to be described later flows downward (for example, in the third direction D3).

The scrubbing apparatus 200 according to some embodiments may further include first_2 scrubbing holes 223H and a first_2 scrubbing wall 224.

The first_2 scrubbing holes 223H may be formed in the first_2 scrubbing plate 223. The first_2 scrubbing holes 223H may extend from a lower surface of the first_2 scrubbing plate 223 to an upper surface of the first_2 scrubbing plate 223. The first_2 scrubbing holes 223H may penetrate the first_2 scrubbing plate 223 in the third direction D3. Gas may ascend in the third direction D3 through the first_2 scrubbing holes 223H.

The lower surface of the first_2 scrubbing plate 223 may face the upper surface of the first_1 scrubbing plate 221. The upper surface of the first_2 scrubbing plate 223 may be opposite to the lower surface of the first_2 scrubbing plate 223 in the third direction D3.

The first_2 scrubbing wall 224 may be attached to the other end of the first_2 scrubbing plate 223. The first_2 scrubbing wall 224 may be interposed between the first_2 scrubbing plate 223 and the inner side wall of the first scrubbing chamber 22. The first_2 scrubbing wall 224 may extend in the third direction D3. In some embodiments, a portion of the first_2 scrubbing wall 224 may protrude in the third direction D3 from the upper surface of the first_2 scrubbing plate 223. Another portion of the first_2 scrubbing wall 224 may protrude in the third direction D3 from the lower surface of the first_2 scrubbing plate 223.

A length of a portion of the first_2 scrubbing wall 224 protruding in the third direction D3 from the upper surface of the first_2 scrubbing plate 223 may be smaller than a length, in the third direction D3, of a portion protruding in the third direction D3 from the lower surface of the first_2 scrubbing plate 223, but the technical scope of the present disclosure is not limited thereto.

In FIG. 5, a portion of the first_1 scrubbing wall 222 protruding in the third direction D3 from the upper surface of the first_1 scrubbing plate 221 may have a first height H1. The first height H1 may be a vertical length in the third direction D3 from the upper surface of the first_1 scrubbing plate 221 to an upper surface of the first_1 scrubbing wall 222. A second height H2 in the third direction D3 from the upper surface of the first_1 scrubbing plate 221 to the first_2 scrubbing wall 224 may be equal to the first height H1.

Accordingly, when bubbles BBL are formed on the upper surface of the first_1 scrubbing plate 221, a phenomenon in which the gas ascends through a space between the first_2 scrubbing wall 224 and the first scrubbing chamber 22 may be effectively suppressed. As a result, the scrubbing apparatus 200 having improved scrubbing efficiency may be provided.

In some embodiments, the first_1 scrubbing plate 221 and the first_2 scrubbing plate 223 are not completely overlapped in the third direction D3. The first_1 scrubbing plate 221 and the first_2 scrubbing plate 223 may be arranged in a zigzag manner. Accordingly, the first scrubbing solution 226 that has flowed downward beyond the first_2 scrubbing wall 224 may be discharged onto the upper surface of the first_1 scrubbing plate 221. In other words, a center of the first_1 scrubbing plate 221 and a center of the first_2 scrubbing plate 223 may be offset from each other.

In some embodiments, the first_1 and first_2 scrubbing holes 221H and 223H may be completely overlapped in the third direction D3. However, the technical scope of the present disclosure is not limited thereto. The first_1 and first_2 scrubbing holes 221H and 223H may not be completely overlapped in the third direction D3, or may be partially overlapped.

In some embodiments, the first scrubbing solution 226 may be water. However, the technical scope of the present disclosure is not limited thereto.

The first scrubbing solution 226 may be discharged onto the upper surface of the first_2 scrubbing plate 223. For example, the first scrubbing solution 226 may be discharged at a position farthest from the first_2 scrubbing wall 224. After being discharged onto the upper surface of the first_2 scrubbing plate 223, the first scrubbing solution 226 may flow toward the first_2 scrubbing wall 224 on the upper surface of the first_2 scrubbing plate 223 while the first scrubbing process is performed. At this time, the first scrubbing solution 226 does not flow downward through the first_2 scrubbing holes 223H. The first scrubbing solution 226 may flow over the first_2 scrubbing wall 224 and downward to the lower part of the first scrubbing chamber 22.

The first scrubbing solution 226 having flowed over the first_2 scrubbing wall 224 is discharged again onto the upper surface of the first_1 scrubbing plate 221. The first scrubbing solution 226 may flow toward the first_1 scrubbing wall 222 on the upper surface of the first_1 scrubbing plate 221 while the first scrubbing process is performed.

The first scrubbing solution 226 disposed on the upper surface of the first_1 scrubbing plate 221 does not flow downward through the first_1 scrubbing holes 221H. The first scrubbing solution 226 may flow over the first_1 scrubbing wall 222 and downward to the lower part of the first scrubbing chamber 22.

Finally, the first scrubbing solution 226 having flowed over the first_1 scrubbing wall 222 may be stored in the first scrubbing solution storage tank 228 provided at the lower part of the first scrubbing chamber 22. The first scrubbing solution 227 in which impurities are dissolved may be stored in the first scrubbing solution storage tank 228. For example, the first scrubbing solution 227 in which the impurities are dissolved may be a solution in which hydrophilic gas is dissolved in the first scrubbing solution 226.

In some embodiments, the hydrophilic gas may be IPA (isopropyl alcohol) and/or ammonia, but the technical scope of the present disclosure is not limited thereto.

In some embodiments, the first scrubbing solution storage tank 228 may be overlapped with the first inlet chamber 21 and the first scrubbing chamber 22 in the third direction D3. That is, the first inlet chamber 21 and the first scrubbing chamber 22 are adjacent to each other in the first direction D1, and the first scrubbing solution storage tank 228 may be disposed below the first inlet chamber 21 and the first scrubbing chamber 22. Accordingly, the scrubbing apparatus 200 having improved space efficiency may be provided.

In some embodiments, the second inlet chamber 23 may be adjacent to the first scrubbing chamber 22 in the first direction D1. The second inlet chamber 23 and the first scrubbing chamber 22 may be connected to each other at an upper part of the scrubbing apparatus 200. That is, in the first scrubbing chamber 22, the gas may ascend in the third direction D3 and may be provided to the second inlet chamber 23 at the upper part of the scrubbing apparatus 200.

A second pressure controller 230 may be disposed in the second inlet chamber 23. The second inlet chamber 23 may define a second inlet space 23S. The second pressure controller 230 may include a second rotation module. The second rotation module may be rotatable. The second rotation module may rotate in a clockwise direction or a counterclockwise direction. By adjusting a rotation speed of the second rotation module, a pressure of the gas discharged to an outside of the scrubbing apparatus 200 through the second pipe 130 may be controlled to a constant value. By adjusting the rotation speed of the second rotation module, a pressure of the gas provided to the scrubbing apparatus 200 through the first pipe 120 may also be controlled to a constant value.

In some embodiments, a bottom surface 23BS of the second inlet chamber 23 may include a second portion 23BS_2. The second portion 23BS_2 may be inclined downward. That is, the second portion 23BS_2 may extend between the second direction D2 and the third direction D3. A flow path of the gas may be restricted by the second portion 23BS_2. The gas may enter the inside of the second scrubbing chamber 24 along the second portion 23BS_2. Since the second portion 23BS_2 has a shape inclined downward, the gas may also enter downward.

In FIG. 4, the second portion 23BS_2 is illustrated as not being disposed in a second scrubbing solution 247 in which impurities are dissolved, but the technical scope of the present disclosure is not limited thereto. At least a portion of the second portion 23BS_2 may be disposed in the second scrubbing solution 247 in which the impurities are dissolved.

In some embodiments, the bottom surface 23BS of the second inlet chamber 23 may restrict a flow path of the gas. For example, when the gas directly contacts water while descending in the third direction D3, the water may splash and flow into the second pressure controller 230. By forming the bottom surface 23BS of the second inlet chamber 23 to restrict the flow path of the gas, this may be prevented.

The second scrubber may be interposed at one side of the second inlet chamber 23. The second scrubber may include a second scrubbing chamber 24, a second_1 scrubbing plate 241, a second_2 scrubbing plate 243, a second_1 scrubbing wall 242, a second_2 scrubbing wall 244, a second solution supply nozzle 245, and a demister 249.

The second scrubbing chamber 24 may be an outer housing of the second scrubber. The gas may be provided into the second scrubbing chamber 24. The gas may contain impurities. The gas may pass through the first inlet chamber 21, the first scrubbing chamber 22, and the second inlet chamber 23 and be provided to the second scrubbing chamber 24.

In the second scrubbing chamber 24, impurities contained in the gas may be dissolved in a second scrubbing solution 246. The second scrubbing chamber 24 may define a second scrubbing space 24S. The second scrubbing space 24S may be a space in which a second scrubbing process, in which impurities contained in the gas are dissolved in the scrubbing solution, is performed.

A plurality of second scrubbing plates may be disposed in the second scrubbing space 24S. The plurality of second scrubbing plates may include, for example, a second_1 scrubbing plate 241 and a second_2 scrubbing plate 243.

In FIG. 4, the second scrubber is illustrated as including two second scrubbing plates, but the technical scope of the present disclosure is not limited thereto. The second scrubber according to some embodiments of the present disclosure may include one or more second scrubbing plates. That is, one second scrubbing plate may be disposed in the second scrubbing space 24S, or three or more second scrubbing plates may be disposed therein.

The second_1 scrubbing plate 241 may be disposed at a lowermost position among the second scrubbing plates disposed in the second scrubbing space 24S. One end of the second_1 scrubbing plate 241 may be connected to and fixed to an inner side wall of the second scrubbing chamber 24, and the other end of the second_1 scrubbing plate 241 may be spaced apart from the inner side wall of the second scrubbing chamber 24 in the second direction D2. Specifically, three surfaces of the second_1 scrubbing plate 241 may be connected to the inner side wall of the second scrubbing chamber 24, and a remaining one surface of the second_1 scrubbing plate 241 may not be connected to the inner side wall of the second scrubbing chamber 24. The second_1 scrubbing plate 241 may be disposed on a plane extending in the first direction D1 and the second direction D2. A space from the other end of the second_1 scrubbing plate 241 to the inner side wall of the second scrubbing chamber 24 may be a space through which the second scrubbing solution 246 to be described later flows downward (for example, in the third direction D3).

The second scrubber according to some embodiments may further include second_1 scrubbing holes 241H and a second_1 scrubbing wall 242.

The second_1 scrubbing holes 241H may be formed in the second_1 scrubbing plate 241. The second_1 scrubbing holes 241H may extend from a lower surface of the second_1 scrubbing plate 241 to an upper surface of the second_1 scrubbing plate 241. That is, the second_1 scrubbing holes 241H may penetrate the second_1 scrubbing plate 241 in the third direction D3. Gas may ascend in the third direction D3 through the second_1 scrubbing holes 241H.

The lower surface of the second_1 scrubbing plate 241 may face a second scrubbing solution storage tank 248 to be described later. The upper surface of the second_1 scrubbing plate 241 may face the second_2 scrubbing plate 243. The upper surface of the second_1 scrubbing plate 241 may be opposite to the lower surface of the second_1 scrubbing plate 241 in the third direction D3.

The second_1 scrubbing wall 242 may be attached to the other end of the second_1 scrubbing plate 241. The second_1 scrubbing wall 242 may be interposed between the second_1 scrubbing plate 241 and an inner side wall of the second scrubbing chamber 24. The second_1 scrubbing wall 242 may extend in the third direction D3. In some embodiments, a portion of the second_1 scrubbing wall 242 may protrude from an upper surface of the second_1 scrubbing plate 241 in the third direction D3. Another portion of the second_1 scrubbing wall 242 may protrude from a lower surface of the second_1 scrubbing plate 241 in the third direction D3.

A length of a portion of the second_1 scrubbing wall 242 protruding in the third direction D3 from the upper surface of the second_1 scrubbing plate 241 may be smaller than a length, in the third direction D3, of a portion protruding in the third direction D3 from the lower surface of the second_1 scrubbing plate 241, but the technical scope of the present disclosure is not limited thereto.

In some embodiments, at least a portion of the second_1 scrubbing wall 242 may be disposed in the second scrubbing solution 247 in which impurities are dissolved, but the technical scope of the present disclosure is not limited thereto. Since at least a portion of the second_1 scrubbing wall 242 is disposed in the second scrubbing solution 247 in which the impurities are dissolved, the gas may initially ascend in the third direction D3 through the second_1 scrubbing holes 241H. Since at least a portion of the second_1 scrubbing wall 242 is disposed in the second scrubbing solution 247 in which the impurities are dissolved, the gas may not ascend into a space between the second_1 scrubbing wall 242 and the inner side wall of the second scrubbing chamber 24.

The second_2 scrubbing plate 243 may be disposed on the second_1 scrubbing plate 241. Specifically, the second_2 scrubbing plate 243 may be disposed on the upper surface of the second_1 scrubbing plate 241.

Similar to the second_1 scrubbing plate 241, one end of the second_2 scrubbing plate 243 may be connected to and fixed to the inner side wall of the second scrubbing chamber 24, and the other end of the second_2 scrubbing plate 243 may be spaced apart from the inner side wall of the second scrubbing chamber 24 in the second direction D2. Specifically, three surfaces of the second_2 scrubbing plate 243 may be connected to and fixed to the inner side wall of the second scrubbing chamber 24. However, a remaining one surface of the second_2 scrubbing plate 243 may not be connected to and fixed to the inner side wall of the second scrubbing chamber 24. The one surface of the second_2 scrubbing plate 243 may be spaced apart from the inner side wall of the second scrubbing chamber 24 in the second direction D2. A space from the other end of the second_2 scrubbing plate 243 to the second scrubbing chamber 24 may be a space through which the second scrubbing solution 246 to be described later flows downward (for example, in the third direction D3).

The scrubbing apparatus 200 according to some embodiments may further include second_2 scrubbing holes 243H and a second_2 scrubbing wall 244.

The second_2 scrubbing holes 243H may be formed in the second_2 scrubbing plate 243. The second_2 scrubbing holes 243H may extend from a lower surface of the second_2 scrubbing plate 243 to an upper surface of the second_2 scrubbing plate 243. The second_2 scrubbing holes 243H may penetrate the second_2 scrubbing plate 243 in the third direction D3. Gas may ascend in the third direction D3 through the second_2 scrubbing holes 243H.

The lower surface of the second_2 scrubbing plate 243 may face the upper surface of the second_1 scrubbing plate 241. The upper surface of the second_2 scrubbing plate 243 may be opposite to the lower surface of the second_2 scrubbing plate 243 in the third direction D3.

The second_2 scrubbing wall 244 may be attached to the one surface of the second_2 scrubbing plate 243. The second_2 scrubbing wall 244 may be interposed between the second_2 scrubbing plate 243 and the inner side wall of the second scrubbing chamber 24. The second_2 scrubbing wall 244 may extend in the third direction D3. In some embodiments, a portion of the second_2 scrubbing wall 244 may protrude in the third direction D3 from the upper surface of the second_2 scrubbing plate 243. Another portion of the second_2 scrubbing wall 244 may protrude in the third direction D3 from the lower surface of the second_2 scrubbing plate 243.

A length of a portion of the second_2 scrubbing wall 244 protruding in the third direction D3 from the upper surface of the second_2 scrubbing plate 243 may be smaller than a length, in the third direction D3, of a portion protruding in the third direction D3 from the lower surface of the second_2 scrubbing plate 243, but the technical scope of the present disclosure is not limited thereto.

Although not illustrated, similar to the first scrubber, a portion of the second_1 scrubbing wall 242 protruding in the third direction D3 from the upper surface of the second_1 scrubbing plate 241 may have a third height. The third height may be a vertical length in the third direction D3 from the upper surface of the second_1 scrubbing plate 241 to an upper surface of the second_1 scrubbing wall 242. A fourth height in the third direction D3 from the upper surface of the second_1 scrubbing plate 241 to the second_2 scrubbing wall 244 may be equal to the third height.

Accordingly, when bubbles BBL are formed on the upper surface of the second_1 scrubbing plate 241, a phenomenon in which the gas ascends through a space between the second_2 scrubbing wall 244 and the second scrubbing chamber 24 may be effectively suppressed. As a result, the scrubbing apparatus 200 having improved scrubbing efficiency may be provided.

In some embodiments, the second scrubbing solution 246 may be water. However, the technical scope of the present disclosure is not limited thereto.

The second scrubbing solution 246 may be discharged onto the upper surface of the second_2 scrubbing plate 243. For example, the second scrubbing solution 246 may be discharged at a position farthest from the second_2 scrubbing wall 244. After being discharged onto the upper surface of the second_2 scrubbing plate 243, the second scrubbing solution 246 may flow toward the second_2 scrubbing wall 244 on the upper surface of the second_2 scrubbing plate 243 while the second scrubbing process is performed. At this time, the second scrubbing solution 246 does not flow downward through the second_2 scrubbing holes 243H. The second scrubbing solution 246 may flow over the second_2 scrubbing wall 244 and downward to a lower part of the second scrubbing chamber 24.

The second scrubbing solution 246 having flowed over the second_2 scrubbing wall 244 is discharged again onto the upper surface of the second_1 scrubbing plate 241. The second scrubbing solution 246 may flow toward the second_1 scrubbing wall 242 on the upper surface of the second_1 scrubbing plate 241 while the second scrubbing process is performed.

The second scrubbing solution 246 disposed on the upper surface of the second_1 scrubbing plate 241 does not flow downward through the second_1 scrubbing hole 241H. The second scrubbing solution 246 may flow over the second_1 scrubbing wall 242 and downward to the lower part of the second scrubbing chamber 24.

Finally, the second scrubbing solution 246 having flowed over the second_1 scrubbing wall 242 may be stored in the second scrubbing solution storage tank 248 provided at the lower part of the second scrubbing chamber 24. The second scrubbing solution 247 in which impurities are dissolved may be stored in the second scrubbing solution storage tank 248. For example, the second scrubbing solution 247 in which the impurities are dissolved may be a solution in which hydrophilic gas is dissolved in the second scrubbing solution 246.

In some embodiments, the hydrophilic gas may be IPA (isopropyl alcohol) and/or ammonia, but the technical scope of the present disclosure is not limited thereto.

In some embodiments, the second scrubbing solution storage tank 248 may be overlapped with the second inlet chamber 23 and the second scrubbing chamber 24 in the third direction D3. That is, the second inlet chamber 23 and the second scrubbing chamber 24 are adjacent to each other in the second direction D2, and the second scrubbing solution storage tank 248 may be disposed below the second inlet chamber 23 and the second scrubbing chamber 24. Accordingly, the scrubbing apparatus 200 having improved space efficiency may be provided.

In some embodiments, the demister 249 may be disposed at an upper part of the second scrubbing chamber 24. The demister 249 may be used to remove moisture from the gas after the first scrubbing process and the second scrubbing process are performed. After the first scrubbing process and the second scrubbing process are performed, gas from which impurities are partially removed may be provided. That is, by using the demister 249, moisture may be removed from the gas from which impurities are partially removed after the first scrubbing process and the second scrubbing process are performed.

When the scrubbing apparatus 200 according to some embodiments is used, a contact area between the gas and the scrubbing solution may be increased. Specifically, by forming bubbles in the scrubbing solution, the contact area between the scrubbing solution and the gas may be increased.

For example, in FIG. 6, the gas may pass through the first_1 scrubbing holes 221H and ascend in the third direction D3 (see reference numeral 221u).

After the gas ascends through the first_1 scrubbing holes 221H, bubbles BBL may be formed on the upper surface of the first_1 scrubbing plate 221. The bubbles BBL may be formed due to a pressure at which the gas tends to ascend in the third direction D3 in the first scrubbing solution 226. The bubbles BBL may be formed inside the first scrubbing solution 226. At portions where the bubbles BBL contact the first scrubbing solution 226, impurities contained in the gas may be dissolved in the first scrubbing solution 226.

Although not illustrated, after the gas ascends through the first_1 scrubbing holes 221H, the gas may ascend in the third direction D3 by passing through the first_2 scrubbing holes 223H. After the gas ascends through the first_2 scrubbing holes 223H, bubbles may be formed on the upper surface of the first_2 scrubbing plate 223.

In addition, in the second scrubbing chamber 24, the gas may ascend in the third direction D3 by passing through the second_1 scrubbing holes 241H. After the gas ascends through the second_1 scrubbing holes 241H, bubbles may be formed on the upper surface of the second_1 scrubbing plate 241. Thereafter, the gas may ascend in the third direction D3 by passing through the second_2 scrubbing holes 243H. After the gas ascends through the second_2 scrubbing holes 243H, bubbles may be formed on the upper surface of the second_2 scrubbing plate 243.

When bubbles BBL are formed in the first scrubbing solution 226 or the second scrubbing solution 246, a contact area between the gas and the scrubbing solution may be increased. Accordingly, the scrubbing apparatus 200 having improved scrubbing efficiency may be provided.

When the scrubbing apparatus 200 according to some embodiments is used, gas harmful to the human body (for example, impurities) may be dissolved in the scrubbing solution. Accordingly, gas harmful to the human body may be removed from by-products generated after various semiconductor processes are performed and discharged to an outside of the scrubbing apparatus 200.

The scrubbing apparatus 200 according to some embodiments may include a first pressure sensor 29a, a second pressure sensor 29b, a third pressure sensor 29c, a fourth pressure sensor 29d, and a fifth pressure sensor 29e.

The first pressure sensor 29a may measure a first pressure of the gas provided to the first inlet chamber 21. The second pressure sensor 29b may measure a second pressure of the gas inside the first scrubbing chamber 22. The third pressure sensor 29c may measure a third pressure of the gas inside the second inlet chamber 23. The fourth pressure sensor 29d may measure a fourth pressure of the gas inside the second scrubbing chamber 24. The fifth pressure sensor 29e may measure a fifth pressure of the gas discharged to an outside of the second scrubbing chamber 24. The scrubbing apparatus 200 may be controlled by measuring the first to fifth pressures. For example, the controller may control the scrubbing apparatus 200.

When the scrubbing apparatus 200 according to some embodiments is used, a pressure of the gas passing through the first pipe 120 and a pressure of the gas passing through the second pipe 130 may be controlled to be constant. For example, the pressure of the gas passing through the first pipe 120 may be controlled to be lower than a maximum pressure applicable to the process chamber 100. The pressure of the gas passing through the second pipe 130 may be controlled to be 0 Pa.

In some embodiments, when an absolute value of the first pressure measured by the first pressure sensor is greater than a first pressure set value, a rotation speed of the first rotation module of the first pressure controller 210 may be decreased. That is, when the absolute value of the first pressure is greater than the first pressure set value, RPM (rotations per minute) of the first rotation module may be decreased. The first pressure set value may be 500 Pa or more and 1500 Pa or less, but the technical scope of the present disclosure is not limited thereto.

This may be because, when the rotation speed of the first rotation module decreases, the absolute value of the first pressure of the gas passing through the first pipe 120 decreases.

In some embodiments, as the absolute value of the first pressure becomes greater than the first pressure set value, the RPM of the first rotation module may decrease more rapidly. This may be to adjust the absolute value of the first pressure to be equal to the first pressure set value more quickly as a difference between the absolute value of the first pressure and the first pressure set value increases. Accordingly, stability of the process chamber 100 connected to the first pipe 120 may be improved.

Conversely, when the absolute value of the first pressure measured by the first pressure sensor 29a is less than the first pressure set value, the rotation speed of the first rotation module may be increased. That is, when the absolute value of the first pressure measured by the first pressure sensor 29a is less than the first pressure set value, the RPM (rotations per minute) of the first rotation module may be increased.

This may be because, when the rotation speed of the first rotation module increases, the absolute value of the first pressure of the gas passing through the first pipe 120 increases.

In some embodiments, as the absolute value of the first pressure becomes smaller than the first pressure set value, the RPM of the first rotation module may increase more rapidly. This may be to adjust the absolute value of the first pressure to be equal to the first pressure set value more quickly as a difference between the absolute value of the first pressure and the first pressure set value increases. Accordingly, stability of the process chamber 100 connected to the first pipe 120 may be improved.

According to some embodiments, when the absolute value of the first pressure measured by the first pressure sensor 29a is greater than the first pressure set value, rotation speeds of the first rotation module of the first pressure controller 210 and the second rotation module of the second pressure controller 230 may be decreased, respectively. Conversely, when the absolute value of the first pressure measured by the first pressure sensor 29a is less than the first pressure set value, the rotation speeds of the first rotation module of the first pressure controller 210 and the second rotation module of the second pressure controller 230 may be increased, respectively.

As described above, by controlling the first pressure using both the first pressure controller 210 and the second pressure controller 230, a load applied to each pressure controller may be reduced, and the first pressure may be quickly adjusted to match the first pressure set value. Accordingly, overall stability of the system may be effectively improved.

In some embodiments, the number of process chambers 100 connected to the first inlet chamber 21 may be one or more. For example, when the number of process chambers 100 connected to the first inlet chamber 21 decreases from three to two, the first pressure of the gas passing through the first pipe 120 may decrease. This may be because a flow rate of the gas passing through the first pipe 120 decreases. In this case, a rotation speed of the first rotation module of the first pressure controller 210 may be increased. Alternatively, a rotation speed of the second rotation module of the second pressure controller 230 may be increased. Conversely, when the number of process chambers 100 connected to the first inlet chamber 21 increases from three to four, the first pressure of the gas passing through the first pipe 120 may increase. This may be because the flow rate of the gas passing through the first pipe 120 increases. In this case, the rotation speed of the first rotation module of the first pressure controller 210 may be decreased. Alternatively, the rotation speed of the second rotation module of the second pressure controller 230 may be decreased.

According to some embodiments, the second pressure measured by the second pressure sensor 29b may be divided into first to third sections. An absolute value of the second pressure in the first section may be smaller than an absolute value of the second pressure in the second section. An absolute value of the second pressure in the second section may be smaller than an absolute value of the second pressure in the third section.

When the second pressure is in the first section, it may be determined that bubbles are not formed on the upper surface of the first scrubbing plate in the first scrubbing chamber 22. In this case, a flow rate of the first scrubbing solution 226 provided onto the upper surface of the first scrubbing plate may be increased. When the second pressure is in the second section, it may be determined that the first scrubber is operating normally. When the second pressure is in the third section, it may be determined that the first scrubber is not operating normally. In this case, operation of the scrubbing apparatus 200 may be stopped. However, the technical scope of the present disclosure is not limited thereto.

According to some embodiments, the third pressure measured by the third pressure sensor 29c may be used as data for determining whether the scrubbing system is operating normally.

According to some embodiments, the fourth pressure measured by the fourth pressure sensor 29d may be divided into fourth to sixth sections. An absolute value of the fourth pressure in the fourth section may be smaller than an absolute value of the fourth pressure in the fifth section. An absolute value of the fourth pressure in the fifth section may be smaller than an absolute value of the fourth pressure in the sixth section.

When the fourth pressure is in the fourth section, it may be determined that bubbles are not formed on an upper surface of the second scrubbing plate in the second scrubbing chamber 24. In this case, a flow rate of the second scrubbing solution 246 provided onto the upper surface of the second scrubbing plate may be increased. When the fourth pressure is in the fifth section, it may be determined that the second scrubber is operating normally. When the fourth pressure is in the sixth section, it may be determined that the second scrubber is not operating normally. In this case, operation of the scrubbing apparatus 200 may be stopped. However, the technical scope of the present disclosure is not limited thereto.

In some embodiments, when an absolute value of the fifth pressure measured by the fifth pressure sensor 29e is greater than a second pressure set value, a rotation speed of the second rotation module of the second pressure controller 230 may be decreased. That is, when the absolute value of the fifth pressure is greater than the second pressure set value, RPM (rotations per minute) of the second rotation module may be decreased. The second pressure set value may be approximately 0 Pa, but the technical scope of the present disclosure is not limited thereto.

This may be because, when the rotation speed of the second rotation module decreases, the absolute value of the fifth pressure of the gas passing through the second pipe 130 decreases.

In some embodiments, as the absolute value of the fifth pressure becomes greater than the second pressure set value, the RPM of the second rotation module may decrease more rapidly. This may be to adjust the absolute value of the fifth pressure to be equal to the second pressure set value more quickly as a difference between the absolute value of the fifth pressure and the second pressure set value increases. Accordingly, stability of the utility duct 300 connected to the second pipe 130 may be improved.

Conversely, when the absolute value of the fifth pressure measured by the fifth pressure sensor 29e is less than the second pressure set value, the rotation speed of the second rotation module may be increased. That is, when the absolute value of the fifth pressure measured by the fifth pressure sensor 29e is less than the second pressure set value, the RPM (rotations per minute) of the second rotation module may be increased.

This may be because, when the rotation speed of the second rotation module increases, the absolute value of the fifth pressure of the gas passing through the second pipe 130 increases.

In some embodiments, as the absolute value of the fifth pressure becomes smaller than the second pressure set value, the RPM of the second rotation module may increase more rapidly. This may be to adjust the absolute value of the fifth pressure to be equal to the second pressure set value more quickly as a difference between the absolute value of the fifth pressure and the second pressure set value increases. Accordingly, stability of the utility duct 300 connected to the second pipe 130 may be improved.

According to some embodiments, the first pressure controller 210 may be disposed on the front of the first scrubber, and the second pressure controller 230 may be disposed on the front of the second scrubber. By using the first pressure controller 210 and the second pressure controller 230, the pressure of the gas passing through the second pipe 130 may be maintained at 0 Pa. This is because the pressure of the gas is reduced while passing through the first scrubber and the second scrubber. By maintaining the pressure of the gas passing through the second pipe 130 at 0 Pa, a load applied to the utility duct 300 may be reduced.

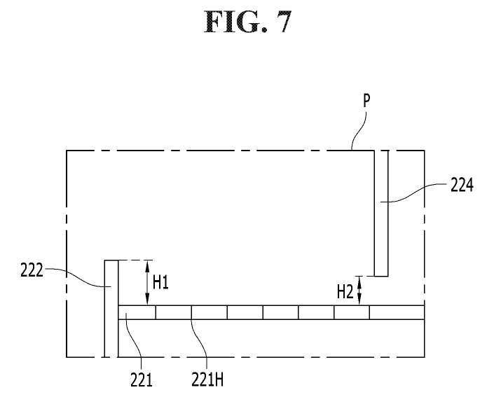

Referring to FIGS. 7-13, a scrubbing apparatus according to other embodiments of the present disclosure will be described below. For convenience of explanation, descriptions overlapping with those described with reference to FIGS. 1-6 will be briefly described or omitted.

FIG. 7 is a drawing for explaining the scrubbing apparatus according to some other embodiments of the present disclosure. For reference, FIG. 7 may be an enlarged exemplary view of region P of FIG. 3.

Referring to FIG. 7, the first height H1 may be greater than the second height H2. Accordingly, a space between the second_2 scrubbing wall 224 and the first scrubbing chamber 22 may be blocked at an earlier stage. As a result, the scrubbing apparatus 200 having improved efficiency may be provided.

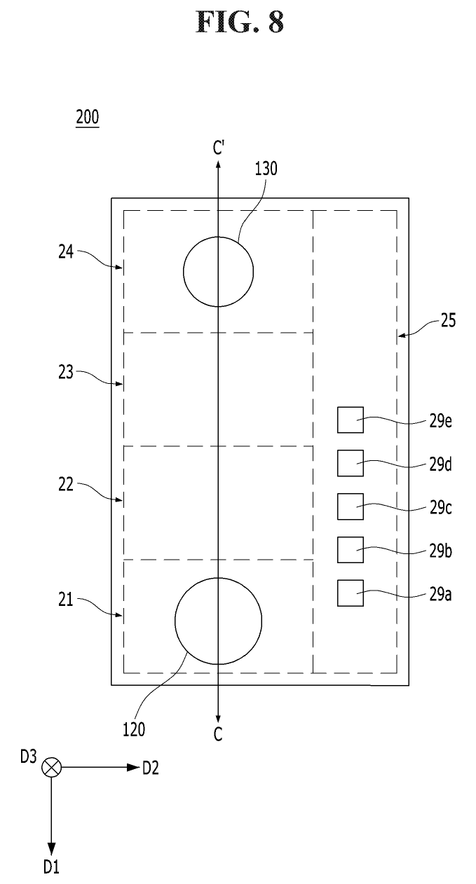

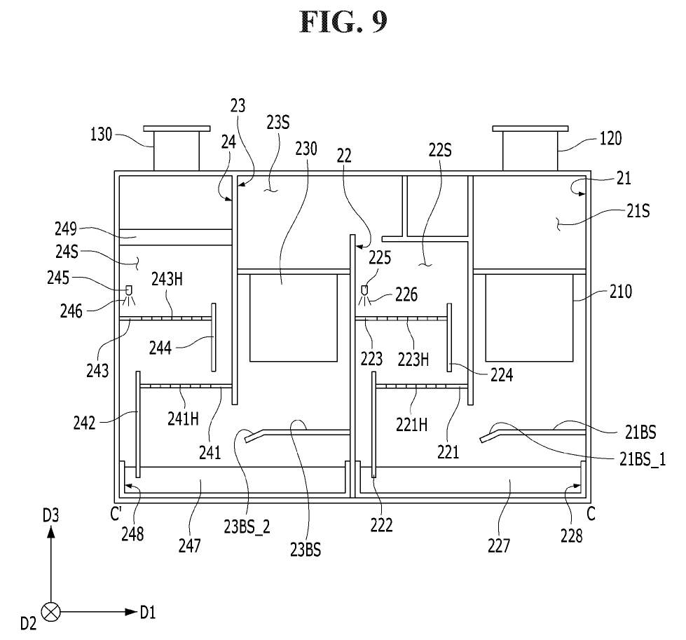

FIG. 8 is a drawing for explaining the scrubbing apparatus according to some other embodiments of the present disclosure. FIG. 9 is a cross-sectional view taken along line C-C' of FIG. 9.

Referring to FIGS. 8 and 9, the first inlet chamber 21, the first scrubbing chamber 22, the second inlet chamber 23, and the second scrubbing chamber 24 may be arranged in the first direction D1. Specifically, the first inlet chamber 21 and the first scrubbing chamber 22 may be adjacent to each other in the first direction D1. The second inlet chamber 23 and the first scrubbing chamber 22 may be adjacent to each other in the first direction D1. The second inlet chamber 23 and the second scrubbing chamber 24 may be adjacent to each other in the first direction D1. The sub-chamber 25 may be disposed at one side of the first inlet chamber 21, the first scrubbing chamber 22, the second inlet chamber 23, and the second scrubbing chamber 24, but the technical scope of the present disclosure is not limited thereto.

In FIG. 9, the bottom surface 21BS of the first inlet chamber 21 may include a first portion 21BS_1. The bottom surface 23BS of the second inlet chamber 23 may include a second portion 23BS_2. The first portion 21BS_1 may be a portion inclined downward. Similarly, the second portion 23BS_2 may also be a portion inclined downward. The first portion 21BS_1 and the second portion 23BS_2 may extend in the same direction. For example, the first portion 21BS_1 and the second portion 23BS_2 may extend in a direction intersecting the first direction D1 and the third direction D3. This may be because the first inlet chamber 21, the first scrubbing chamber 22, the second inlet chamber 23, and the second scrubbing chamber 24 are arranged in the same direction.

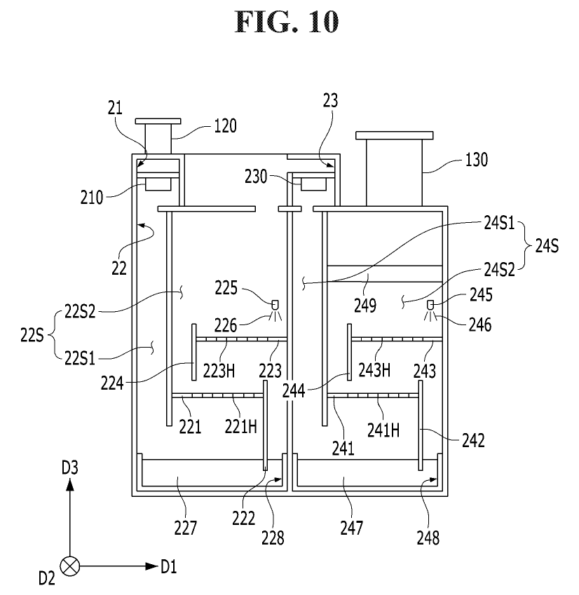

FIGS. 10-13 are drawings for explaining the scrubbing apparatus according to some other embodiments of the present disclosure.

First, referring to FIG. 10, the first scrubbing chamber 22 and the second scrubbing chamber 24 may be adjacent to each other. The second inlet chamber 23 may not be disposed between the first scrubbing chamber 22 and the second scrubbing chamber 24.

Specifically, the first inlet chamber 21 may be disposed on the first scrubbing chamber 22. The first inlet chamber 21 may overlap the first scrubbing chamber 22 in the third direction D3. The first inlet chamber 21 does not overlap the first scrubbing chamber 22 in the first direction D1.

The second inlet chamber 23 may be disposed on the second scrubbing chamber 24. The second inlet chamber 23 may overlap the second scrubbing chamber 24 in the third direction D3. The second inlet chamber 23 does not overlap the second scrubbing chamber 24 in the first direction D1 or the second direction D2.

In some embodiments, the first scrubbing space 22S may include a first_1 scrubbing space 22S1 and a first_2 scrubbing space 22S2. The first_1 scrubbing space 22S1 may be connected to the first inlet chamber 21. The first_1 scrubbing space 22S1 and the first_2 scrubbing space 22S2 may be connected to each other at a lower part of the scrubbing apparatus 200. The gas having passed through the first inlet chamber 21 may be provided to the first_1 scrubbing space 22S1, and thereafter, the gas may move to the first_2 scrubbing space 22S2 at the lower part of the scrubbing apparatus 200. The first scrubbing process may be performed in the first_2 scrubbing space 22S2. The first_2 scrubbing space 22S2 may be connected to the second inlet chamber 23. The first_2 scrubbing space 22S2 and the second inlet space 23S may be connected to each other at the upper part of the scrubbing apparatus 200.

Similarly, the second scrubbing space 24S may include a second_1 scrubbing space 24S1 and a second_2 scrubbing space 24S2. The second_1 scrubbing space 24S1 may be connected to the second inlet chamber 23. The second_1 scrubbing space 24S1 and the second_2 scrubbing space 24S2 may be connected to each other at the lower part of the scrubbing apparatus 200. The gas having passed through the second inlet chamber 23 may be provided to the second_1 scrubbing space 24S1, and thereafter, the gas may move to the second_2 scrubbing space 24S2 at the lower part of the scrubbing apparatus 200. The second scrubbing process may be performed in the second_2 scrubbing space 24S2. The second_2 scrubbing space 24S2 may be connected to the second pipe 130. The gas having completed the second scrubbing process may be discharged to an outside of the scrubbing apparatus 200 through the second pipe 130.

When the scrubbing apparatus 200 according to some embodiments of the present disclosure is used, the inlet chambers may be disposed in a structure integrated with or stacked on the scrubbing chambers. Accordingly, an overall installation area of the scrubbing apparatus 200 may be reduced, thereby effectively decreasing a footprint required in a semiconductor production line. In addition, since efficient utilization of facility space becomes possible, an arrangement density of the semiconductor production line may be increased, and more process chambers may be installed in the same space. As a result, by using the scrubbing apparatus according to the present disclosure, space utilization of the semiconductor production line may be maximized, and both economic efficiency of facility operation and productivity may be improved simultaneously.

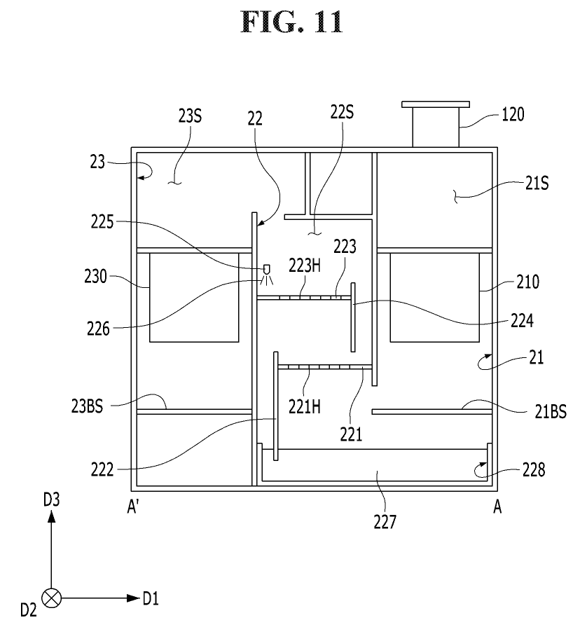

Referring to FIG. 11, a bottom surface of the first inlet chamber 21BS may not include a portion inclined downward. Accordingly, a flow path of the gas provided to the first scrubbing chamber 22 may not be restricted.

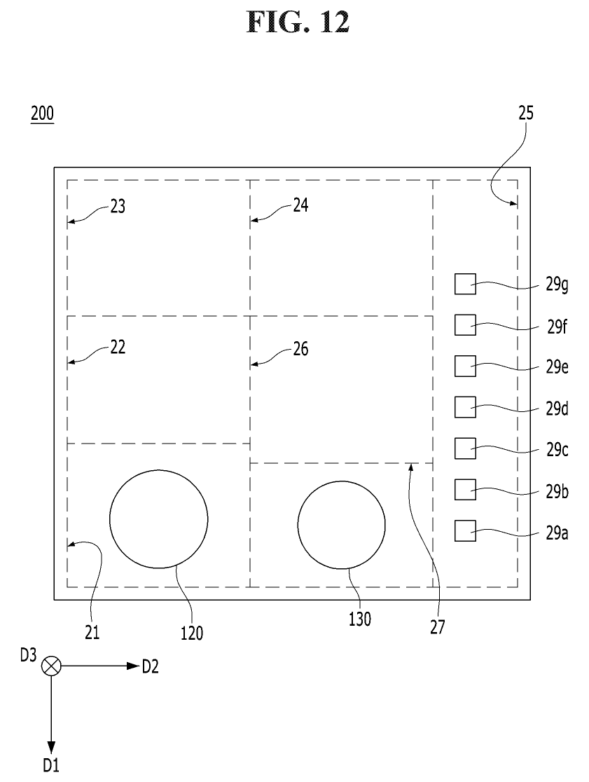

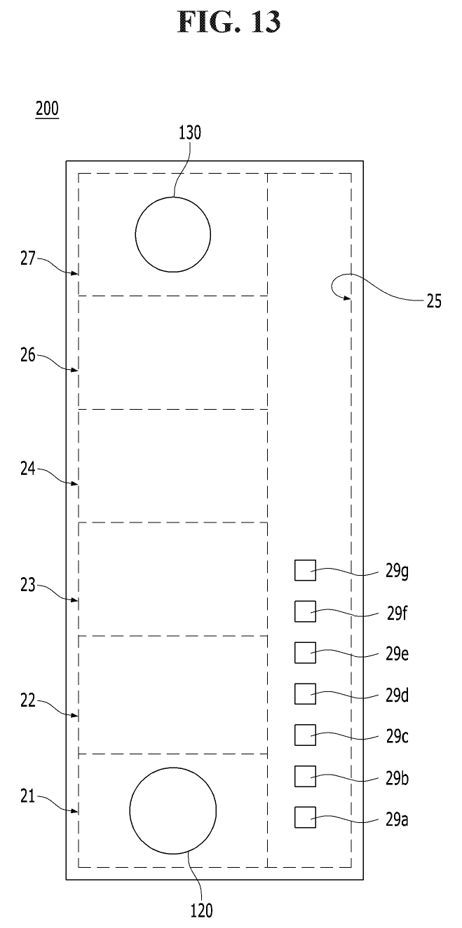

Referring to FIGS. 12 and 13, the scrubbing apparatus 200 according to some embodiments of the present disclosure may include three inlet chambers and three scrubbing chambers.

That is, the scrubbing apparatus 200 may include a first inlet chamber 21, a first scrubbing chamber 22, a second inlet chamber 23, a second scrubbing chamber 24, a third inlet chamber 26, a third scrubbing chamber 27, and a sub-chamber 25. The first pipe 120 may be connected to the first inlet chamber 21, and the second pipe 130 may be connected to the third scrubbing chamber 27.

The scrubbing apparatus 200 according to some embodiments of the present disclosure may further include a sixth pressure sensor 29f and a seventh pressure sensor 29g. In FIGS. 12 and 13, the sixth pressure sensor 29f may measure a sixth pressure of the gas inside the third inlet chamber 26. The seventh pressure sensor 29g may measure a seventh pressure of the gas inside the third scrubbing chamber 27. The fifth pressure sensor 29e may measure the fifth pressure of the gas discharged to an outside of the third scrubbing chamber 27.

The sixth pressure measured by the sixth pressure sensor 29f may be used as data for determining whether the scrubbing system is operating normally.

The seventh pressure measured by the seventh pressure sensor 29g may be divided into seventh to ninth sections. An absolute value of the seventh pressure in the seventh section may be smaller than an absolute value of the seventh pressure in the eighth section. An absolute value of the seventh pressure in the eighth section may be smaller than an absolute value of the seventh pressure in the ninth section.

When the seventh pressure is in the seventh section, it may be determined that bubbles are not formed in the third scrubbing chamber 27. In this case, a flow rate of the third scrubbing solution may be increased. When the seventh pressure is in the eighth section, it may be determined that the third scrubber disposed in the third scrubbing chamber 27 is operating normally. When the seventh pressure is in the ninth section, it may be determined that the third scrubber is not operating normally. In this case, operation of the scrubbing apparatus 200 may be stopped. However, the technical scope of the present disclosure is not limited thereto.

In FIG. 12, the first inlet chamber 21, the first scrubbing chamber 22, and the second inlet chamber 23 may be adjacent to each other in the first direction D1. The first inlet chamber 21, the first scrubbing chamber 22, and the second inlet chamber 23 may be arranged in the first direction D1. The second inlet chamber 23 and the second scrubbing chamber 24 may be adjacent to each other in the second direction D2. The second inlet chamber 23 and the second scrubbing chamber 24 may be arranged in the second direction D2. The second scrubbing chamber 24, the third inlet chamber 26, and the third scrubbing chamber 27 may again be adjacent to each other in the first direction D1. The second scrubbing chamber 24, the third inlet chamber 26, and the third scrubbing chamber 27 may be arranged in the first direction D1. However, the technical scope of the present disclosure is not limited thereto. As the first inlet chamber 21, the first scrubbing chamber 22, the second inlet chamber 23, the second scrubbing chamber 24, the third inlet chamber 26, and the third scrubbing chamber 27 are arranged in a U-shape, a scrubbing apparatus having improved space efficiency may be provided.

In FIG. 13, the first inlet chamber 21, the first scrubbing chamber 22, the second inlet chamber 23, the second scrubbing chamber 24, the third inlet chamber 26, and the third scrubbing chamber 27 may be arranged in a straight line. That is, the first inlet chamber 21, the first scrubbing chamber 22, the second inlet chamber 23, the second scrubbing chamber 24, the third inlet chamber 26, and the third scrubbing chamber 27 may be arranged in the first direction D1. However, the technical scope of the present disclosure is not limited thereto.

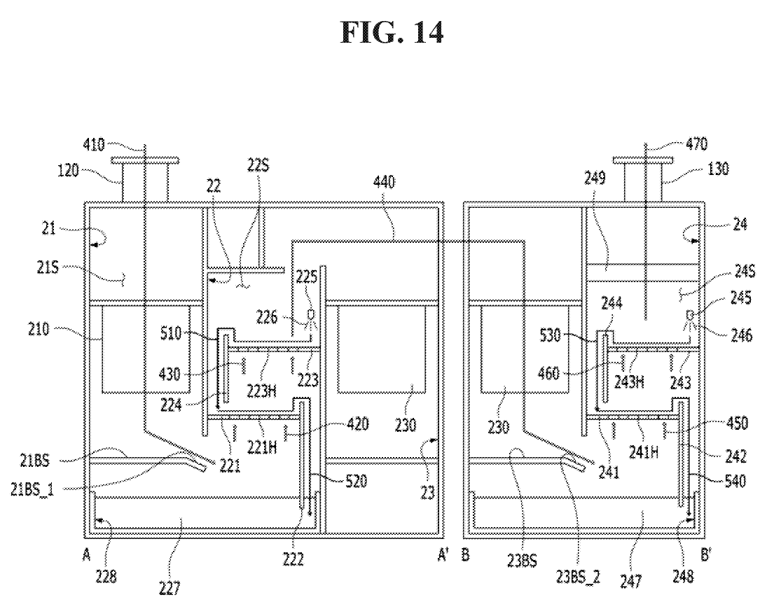

Referring to FIGS. 1 and 14, an operating method of the scrubbing apparatus according to some embodiments of the present disclosure will be described below. FIG. 14 is a drawing for explaining an operating method of a scrubbing apparatus according to some embodiments of the present disclosure. For reference, FIG. 14 may include a cross-sectional view taken along line A-A′ of FIG. 2 and a cross-sectional view taken along line B-B′ of FIG. 2.

Referring to FIGS. 1, 2, and 14, gas containing impurities may be provided from the process chamber 100 to the scrubbing apparatus 200. The gas containing impurities may pass through the first pipe 120 and be introduced into the first inlet chamber 21 (see reference numeral 410).

The gas containing impurities may be introduced into the first inlet space 21S. The gas containing impurities may move toward a lower part of the first inlet space 21S (see reference numeral 410). The gas containing impurities may enter the first scrubbing chamber 22 in a diagonal direction along the first portion 21BS_1 of the bottom surface 21BS of the first inlet chamber 21 (see reference numeral 410). The first inlet chamber 21 and the first scrubbing chamber 22 may be adjacent to each other in the first direction D1.

The gas introduced into the first inlet chamber 21 may have a first pressure. When the first pressure differs from a first pressure set value, the first pressure may be controlled to be equal to the first pressure set value by adjusting a rotational speed of the first rotation module of the first pressure controller 210. When the first pressure differs from the first pressure set value, the first pressure may additionally be controlled to be equal to the first pressure set value by adjusting a rotational speed of the second rotation module of the second pressure controller 230.

In some embodiments, a first scrubbing process may be performed in the first scrubbing space 22S.

While the first scrubbing process is being performed, the first solution supply nozzle 225 may supply the first scrubbing solution 226 onto an upper surface of the first_2 scrubbing plate 223 (see reference numeral 510). Initially supplied first scrubbing solution 226 may flow downward through the first_2 scrubbing holes 223H and the first_1 scrubbing holes 221H. That is, in an initial state, the first scrubbing solution 226 may flow downward through the scrubbing holes 221H and 223H.

During the first scrubbing process, the gas may ascend in the third direction D3. The gas may pass through the first_1 scrubbing holes 221H and ascend in the third direction D3.

Specifically, referring to FIG. 6, the gas may ascend while passing through the first_1 scrubbing holes 221H. As the gas ascends in the third direction D3, bubbles BBL may be formed in the first scrubbing solution 226. At the contact interface where the bubbles BBL come into contact with the first scrubbing solution 226, impurities contained in the gas may be dissolved in the first scrubbing solution 226.

During the first scrubbing process, the first scrubbing solution 226 does not flow downward through the scrubbing holes 221H and 223H (see reference numeral 520). This may be due to the pressure of the gas ascending through the scrubbing holes 221H and 223H.

During the first scrubbing process, the first scrubbing solution 226 flows on the upper surface of the first_2 scrubbing plate 223 toward the first_2 scrubbing wall 224 and may flow over the first_2 scrubbing wall 224 onto the upper surface of the first_1 scrubbing plate 221 (see reference numeral 510). Further, the first scrubbing solution 226 flows on the upper surface of the first_1 scrubbing plate 221 toward the first_1 scrubbing wall 222 and may flow over the first_1 scrubbing wall 222 to the lower part of the first scrubbing chamber 22 (see reference numeral 520).

While the first scrubbing solution 226 flows in the above direction, the gas ascends in the third direction D3 by passing through the scrubbing holes 221H and 223H. As the gas passes through the scrubbing holes 221H and 223H, bubbles may be formed in the first scrubbing solution 226.

Specifically, the gas may ascend through the first_1 scrubbing hole 221H (see reference numeral 420). Subsequently, the gas may ascend through the first_2 scrubbing hole 223H (see reference numeral 430).

As the gas ascends through the scrubbing holes 221H and 223H, impurities contained in the gas may be dissolved in the first scrubbing solution 226. In addition, as the gas ascends through the scrubbing holes 221H and 223H, the pressure of the gas may be reduced due to pressure loss.

In the first scrubbing chamber 22, the gas may have a second pressure. The second pressure may include first to third sections. When the second pressure is in the first section, it may be determined that bubbles are not formed on the upper surface of the first scrubbing plate in the first scrubbing chamber 22. In this case, a flow rate of the first scrubbing solution 226 supplied to the upper surface of the first scrubbing plate may be increased. When the second pressure is in the second section, it may be determined that the first scrubber is operating normally. When the second pressure is in the third section, it may be determined that the first scrubber is not operating normally. In this case, an operation of the scrubbing apparatus 200 may be stopped.

Subsequently, the gas from which impurities have been partially removed may be discharged to an outside of the first scrubbing chamber 22 (see reference numeral 440). The gas from which impurities have been partially removed may be provided to the second inlet chamber 23 (see reference numeral 440). The second inlet chamber 23 and the first scrubbing chamber 22 may be adjacent to each other in the first direction D1.

The gas from which impurities have been partially removed may move to a lower part of the second inlet space 23S (see reference numeral 410). The gas from which impurities have been partially removed may enter the second scrubbing chamber 24 in a diagonal direction along the second portion 23BS_2 of the bottom surface 23BS of the second inlet chamber 23 (see reference numeral 440). The second inlet chamber 23 and the second scrubbing chamber 24 may be adjacent to each other in the second direction D2.

In the second scrubbing chamber 24, impurities contained in the gas may be secondarily scrubbed. For example, the gas provided to the second scrubbing chamber 24 may be introduced into the second scrubbing space 24S, and a second scrubbing process may be performed in the second scrubbing space 24S.

During the second scrubbing process, the second solution supply nozzle 245 may supply the second scrubbing solution 246 onto the upper surface of the second_2 scrubbing plate 243. The initially supplied second scrubbing solution 246 may flow downward through the second_2 scrubbing hole 243H and the second_1 scrubbing hole 241H. That is, in an initial state, the second scrubbing solution 246 may pass through the scrubbing holes 243H and 241H and flow downward.

During the second scrubbing process, the gas may ascend in the third direction D3. The gas may pass through the second_1 scrubbing hole 241H and ascend in the third direction D3 (see reference numeral 450).

During the second scrubbing process, the second scrubbing solution 246 does not flow downward through the scrubbing holes 243H and 241H (see reference numeral 540). This may be due to the pressure of the gas ascending through the scrubbing holes 243H and 241H.

During the second scrubbing process, the second scrubbing solution 246 may flow on the upper surface of the second_2 scrubbing plate 243 toward the second_2 scrubbing wall 244, and may flow over the second_2 scrubbing wall 244 onto the upper surface of the second_1 scrubbing plate 241 (see reference numeral 530). In addition, the second scrubbing solution 246 may flow on the upper surface of the second_1 scrubbing plate 241 toward the second_1 scrubbing wall 242, and may flow over the second_1 scrubbing wall 242 to the lower part of the second scrubbing chamber 24 (see reference numeral 540).

While the second scrubbing solution 246 flows in the above direction, the gas may ascend in the third direction D3 through the scrubbing holes 243H and 241H. As the gas passes upward through the scrubbing holes 243H and 241H, bubbles may be formed in the second scrubbing solution 246.

Specifically, the gas may ascend through the second_1 scrubbing hole 241H (see reference numeral 450). Thereafter, the gas may ascend through the second_2 scrubbing hole 243H (see reference numeral 460).

As the gas ascends through the scrubbing holes 243H and 241H, impurities contained in the gas may be dissolved in the second scrubbing solution 246.

Thereafter, the gas from which the impurities have been removed may pass through the demister 249 and may be discharged to the outside of the second scrubbing chamber 24 (see reference numeral 470).

In the second scrubbing chamber 24, the gas may have a fourth pressure. The fourth pressure may include a fourth to a sixth sections. When the fourth pressure is in the fourth section, it may be determined that bubbles are not formed on the upper surface of the second scrubbing plate in the second scrubbing chamber 24. In this case, a flow rate of the second scrubbing solution 246 supplied to the upper surface of the second scrubbing plate may be increased. When the fourth pressure is in the fifth section, it may be determined that the second scrubber is operating normally. When the fourth pressure is in the sixth section, it may be determined that the second scrubber is not operating normally. In this case, the operation of the scrubbing apparatus 200 may be stopped.

The gas discharged to the outside of the second scrubbing chamber 24 may have a fifth pressure. When the fifth pressure is different from the second pressure set value, the rotational speed of the second rotation module of the second pressure controller 230 may be adjusted to control the fifth pressure to be equal to the second pressure set value.

As described above, by using the scrubbing apparatus 200 according to the present disclosure, impurities contained in the gas may be primarily scrubbed by the first scrubber and secondarily scrubbed by the second scrubber. Accordingly, scrubbing efficiency may be improved, and since a plurality of scrubbers are included, space efficiency may also be enhanced.

In addition, by using the scrubbing apparatus 200 according to the present disclosure, the first pressure of the gas supplied from the process chamber 100 to the first inlet chamber 21 may be maintained at a constant level. Further, the second pressure of the gas discharged to the outside of the scrubbing apparatus 200 may also be maintained at a constant level. Accordingly, loads applied to the process chamber 100 and the utility duct 300 may be reduced.

Although the embodiments of the present disclosure have been described with reference to the attached drawings, the present disclosure is not limited to the embodiments described above, but can be manufactured in various different forms, and a person having ordinary skill in the art to which the present disclosure pertains will understand that the present disclosure can be implemented in other specific forms without changing the technical scope or essential features of the present disclosure. Therefore, it should be understood that the embodiments described above are exemplary in all respects and not restrictive.

1. A scrubbing apparatus comprising:
a first inlet chamber connected to a process chamber;
a first scrubbing chamber connected to the first inlet chamber and defining a first scrubbing space for primarily scrubbing gas generated from the process chamber;
a second inlet chamber connected to the first scrubbing chamber;
a second scrubbing chamber connected to the second inlet chamber and defining a second scrubbing space for secondarily scrubbing the gas;
a first pressure controller disposed in the first inlet chamber and configured to maintain a constant pressure of the gas provided from the process chamber to the first inlet chamber; and
a second pressure controller disposed in the second inlet chamber and configured to maintain a constant pressure of the gas discharged from the second scrubbing chamber.

2. The scrubbing apparatus of claim 1, wherein the first inlet chamber, the first scrubbing chamber, and the second inlet chamber are overlapped in a first direction, and
wherein the second inlet and the second scrubbing chamber are overlapped in a second direction intersecting the first direction.

3. The scrubbing apparatus of claim 2, wherein the first inlet chamber and the first scrubbing chamber are connected to each other at a lower part,
wherein a bottom surface of the first inlet chamber includes a first portion inclined downward, and
wherein the first portion extends between the first direction and a third direction intersecting the first and second directions.

4. The scrubbing apparatus of claim 3, wherein the second inlet chamber and the second scrubbing chamber are connected to each other at a lower part,
wherein a bottom surface of the second inlet chamber includes a second portion inclined downward, and
wherein the second portion extends between the second direction and the third direction.

5. The scrubbing apparatus of claim 1, wherein the first inlet chamber is overlapped with the first scrubbing chamber in a third direction, and
wherein the second inlet chamber is overlapped with the second scrubbing chamber in the third direction.

6. The scrubbing apparatus of claim 5, wherein the first scrubbing chamber includes a first_1 scrubbing space and a first_2 scrubbing space, and
wherein the first_1 scrubbing space and the first_2 scrubbing space are connected to each other at a lower part.

7. The scrubbing apparatus of claim 1, further comprising:
a first scrubbing plate disposed in the first scrubbing chamber, at least a portion of which is fixed to an inner side wall of the first scrubbing chamber;
a plurality of first scrubbing holes penetrating the first scrubbing plate;
a first solution supply nozzle configured to supply a first scrubbing solution onto an upper surface of the first scrubbing plate;
a second scrubbing plate disposed in the second scrubbing chamber, at least a portion of which is fixed to an inner side wall of the second scrubbing chamber;
a plurality of second scrubbing holes penetrating the second scrubbing plate; and
a second solution supply nozzle configured to supply a second scrubbing solution onto an upper surface of the second scrubbing plate,
wherein a portion of impurities contained in the gas ascend through the plurality of first scrubbing holes in the first scrubbing chamber and are dissolved in the first scrubbing solution, and
wherein another portion of the impurities contained in the gas ascend through the plurality of second scrubbing holes in the second scrubbing chamber and are dissolved in the second scrubbing solution.

8. The scrubbing apparatus of claim 1, further comprising a first pressure sensor configured to measure a first pressure of the gas provided to the first inlet chamber,
wherein the first pressure controller includes a first rotation module rotatable,
wherein when an absolute value of the first pressure measured by the first pressure sensor is greater than a first pressure set value, a rotation speed of the first rotation module is decreased, and
wherein when the absolute value of the first pressure measured by the first pressure sensor is less than the first pressure set value, the rotation speed of the first rotation module is increased.

9. The scrubbing apparatus of claim 8, wherein the second pressure controller includes a second rotation module rotatable,
wherein when an absolute value of the first pressure is greater than the first pressure set value, rotation speeds of the first rotation module and the second rotation module are simultaneously decreased, and
wherein when the absolute value of the first pressure is less than the first pressure set value, the rotation speeds of the first rotation module and the second rotation module are simultaneously increased.

10. The scrubbing apparatus of claim 1, wherein the second pressure controller includes a second rotation module rotatable,
wherein when an absolute value of the first pressure is greater than a first pressure set value, a rotation speed of the second rotation module is decreased, and
wherein when the absolute value of the first pressure is less than the first pressure set value, the rotation speed of the second rotation module is increased.

11. The scrubbing apparatus of claim 1, further comprising a second pressure sensor configured to measure a second pressure of the gas discharged through the second scrubbing chamber,
wherein the second pressure controller includes a second rotation module rotatable,
wherein when an absolute value of the second pressure measured by the second pressure sensor is greater than a second pressure set value, a rotation speed of the second rotation module is decreased, and
wherein when the absolute value of the second pressure measured by the second pressure sensor is less than the second pressure set value, the rotation speed of the second rotation module is increased.

12. The scrubbing apparatus of claim 11, wherein the second pressure is 0 Pa.

13. A scrubbing apparatus comprising:
a first scrubber configured to primarily scrub gas;
a first inlet chamber disposed at one end of the first chamber;
a first rotation module disposed in the first inlet chamber;
a second scrubber configured to secondarily scrub the gas;
a second inlet chamber disposed between the second scrubber and the first scrubber; and
a second rotation module disposed in the second inlet chamber,
wherein the first scrubber includes:
a first scrubbing chamber defining a first scrubbing space for scrubbing impurities contained in the gas;
a first scrubbing plate disposed in the first scrubbing chamber, at least a portion of which is fixed to an inner side wall of the first scrubbing chamber;
a plurality of first scrubbing holes penetrating the first scrubbing plate; and
a first solution supply nozzle configured to supply a first scrubbing solution onto an upper surface of the first scrubbing plate,
wherein the second scrubber includes:
a second scrubbing chamber defining a second scrubbing space for scrubbing the impurities contained in the gas;
a second scrubbing plate disposed in the second scrubbing chamber, at least a portion of which is fixed to an inner side wall of the second scrubbing chamber;
a plurality of second scrubbing holes penetrating the second scrubbing plate; and
a second solution supply nozzle configured to supply a second scrubbing solution onto an upper surface of the second scrubbing plate,
wherein when a pressure of the gas provided to the first scrubbing chamber is higher than a predetermined value, a rotation speed of the first rotation module is decreased, and
wherein when a pressure of the gas discharged from the second scrubbing chamber is higher than a predetermined value, a rotation speed of the second rotation module is decreased.

14. The scrubbing apparatus of claim 13, wherein a portion of the impurities contained in the gas ascend through the plurality of first scrubbing holes in the first scrubbing chamber and are dissolved in the first scrubbing solution, and
wherein another portion of the impurities contained in the gas ascend through the plurality of second scrubbing holes in the second scrubbing chamber and are dissolved in the second scrubbing solution.

15. The scrubbing apparatus of claim 1, further comprising a third pressure sensor configured to measure a third pressure of the gas in the first scrubbing chamber,
wherein the third pressure includes a first section, a second section, and a third section,
wherein when the third pressure is in the first section, a flow rate of the first scrubbing solution is increased, and
wherein when the third pressure is in the third section, the gas is not introduced into the first scrubbing chamber.

16. The scrubbing apparatus of claim 13, wherein the first scrubber further comprises a first scrubbing solution storage tank in which a first scrubbing solution, in which impurities are dissolved, is stored,
wherein the first inlet chamber is overlapped with the first scrubbing chamber in a first direction, and
wherein the first scrubbing solution storage tank is overlapped with the first inlet chamber and the first scrubbing chamber in a third direction intersecting the first direction.

17. The scrubbing apparatus of claim 16, wherein the first scrubber further comprises a first scrubbing wall attached to one end of the first scrubbing plate, and
wherein at least a portion of the first scrubbing wall is disposed in the first scrubbing solution in which impurities are dissolved.

18. The scrubbing apparatus of claim 13, further comprising:
a first pipe through which the gas is injected into the scrubbing apparatus, and
a second pipe through which the gas is discharged to an outside of the scrubbing apparatus,
wherein the first pipe is not overlapped with the first scrubber in a third direction, and
wherein the second pipe is overlapped with the second scrubber in the third direction.
